(19) United States
(12) Patent Application Publication
(10) Pub. No.: US 2016/0141232 A1
(43) Pub. Date: May 19, 2016

(54) INTEGRATED CIRCUIT PACKAGE

(71) Applicant: Cambridge Silicon Radio Limited, Cambridge (GB)

(72) Inventor: Kevin Cannon, Cambridge (GB)

(21) Appl. No.: 14/548,056

(22) Filed: Nov. 19, 2014

(51) Int. Cl. H01L 23/495; H01L 23/552; H01L 23/367; H01L 21/48; H01L 21/3205; H01L 23/00; H01L 23/043; H01L 23/31; H01L 21/56

(52) U.S. Cl. CPC H01L 23/49568; H01L 23/49503; H01L 23/49541; H01L 23/3107; H01L 23/552; H01L 23/3675; H01L 21/56; H01L 21/32051; H01L 24/83; H01L 24/32; H01L 23/043; H01L 21/4817; H01L 2924/01047; H01L 2224/32245

(57) ABSTRACT

An integrated circuit package comprising a semiconductor die, a lead frame lying in a first plane, at least one conductive pillar structure extending outwardly from the first plane, wherein the lead frame and the at least one conductive pillar structure are formed of sintered conductive material, encapsulation material which encapsulates the semiconductor die, the lead frame and the at least one conductive pillar structure, a conductive layer on an upper face of the package, the conductive layer conductively connecting to the at least one conductive pillar. Methods of manufacturing are also disclosed.

### BACKGROUND

There is an increasing drive to reduce the size of electronic circuitry. A range of integrated circuit packages have been developed with a reduced form factor. FIG. 1 shows an example of a quad flat no-leads (QFN) package 8. An integrated circuit is provided on a die 2 which is secured by adhesive 4 to a pad 3. In this package, leads 5 are internal to the package and contact pads are provided on the lower surface of the package. Wire bonds 6 connect the die to the contact pads 5. Since the leads 5 do not extend outside the footprint of the package, this yields a smaller package.

FIG. 2 shows an example of a flip-chip on lead (FOL) package 10. An integrated circuit is provided on a die 2 which is secured by a solder ball 11 to a lead 5 which extends under the die 2 and so the leads 5, rather than a die attach pad 3, support the die. This package avoids the need for wire bonds and further reduces the overall dimensions of the package.

Integrated circuits are susceptible to Electromagnetic Interference (EMI). EMI interference can be caused by a source which is external to a circuit board, or from other devices on the same circuit board. The problem of EMI between devices is further compounded by reduced spacing of devices on a circuit board. It is known, that to provide EMI shielding to integrated circuit packages can either increase the size of the package to an undesirable extent or can require additional process steps during manufacture which can increase the complexity and cost of manufacturing the package.

The embodiments described below are not limited to implementations which solve any or all of the disadvantages of known arrangements for shielding a package.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

An aspect of the disclosure provides an integrated circuit package comprising: a semiconductor die; a lead frame lying in a first plane; at least one conductive pillar structure extending outwardly from the first plane, wherein the lead frame and the at least one conductive pillar structure are formed of sintered conductive material; encapsulation material which encapsulates the semiconductor die, the lead frame and the at least one conductive pillar structure; a conductive layer on an upper face of the package, the conductive layer conductively connecting to the at least one conductive pillar.

The at least one conductive pillar structure may have a height which is greater than a height of the lead frame.

The at least one conductive pillar structure may extend perpendicularly to the first plane.

The package may comprise a plurality of the conductive pillars.

The plurality of the conductive pillars may be spaced around a perimeter of the lead frame.

The at least one conductive pillar may be located on a perimeter of the package. Alternatively, the at least one conductive pillar may be offset inwardly from a perimeter of the package.

The at least one conductive pillar may comprise a continuous wall of conductive material located around a perimeter of the lead frame.

The wall may be located on a perimeter of the package.

The conductive layer may form at least one of an EMI shield for the package and a thermal shield for the package.

The conductive layer may be a conductive sheet material.

The conductive layer may be sintered conductive material.

The sintered conductive material may be sintered metal.

The sintered conductive material may be sintered silver.

The sintered conductive material may be thermally conductive.

The sintered conductive material may be electrically conductive.

The package may further comprise a thermal pad beneath the semiconductor die. A conductive path may connect the at least one conductive pillar structure to the thermal pad.

Another aspect of the disclosure provides a method of packaging a semiconductor die comprising: forming a lead frame by depositing conductive material onto a surface of a carrier at locations where elements of the lead frame are required; forming at least one conductive pillar structure by depositing the conductive material onto the surface of the carrier at a locations where the at least one conductive pillar structure is required, wherein the conductive material is sintered conductive material; attaching a semiconductor die; connecting the semiconductor die to the lead frame; encapsulating the semiconductor die, the lead frame and the at least one conductive pillar structure to form an encapsulated package; adding a conductive layer to an upper face of the encapsulated package, the conductive layer conductively connecting to the at least one conductive pillar; and removing the carrier.

The at least one conductive pillar structure may be formed with a height which is greater than a height of the lead frame.

The at least one conductive pillar structure may be formed by a plurality of stages of depositing the conductive material with curing between the stages.

Adding a conductive layer may comprise depositing a layer of the conductive material on the upper face of the encapsulated package.

Adding a conductive layer may comprise attaching a conductive sheet to the upper face of the encapsulated package.

Depositing the conductive material may comprise one of: screen printing the conductive material; printing the conductive material.

The preferred features may be combined as appropriate, as would be apparent to a skilled person, and may be combined with any of the aspects of the invention.

### DESCRIPTION OF THE FIGURES

Embodiments of the invention will be described, by way of example, with reference to the following drawings, in which:

FIG. 1 shows a quad flat no-leads (QFN) package;

FIG. 2 shows a flip-chip on lead (FOL) package;

FIGS. 3A-3K show a manufacturing process for forming a package;

FIG. 4 shows a stencil which can be used in the process of FIGS. 3A-3K;

FIG. 5 shows a package mounted to a circuit board;

FIGS. 6A-6E show examples of conductive structures in the package; and

FIG. 7 shows a flow chart of a manufacturing process.

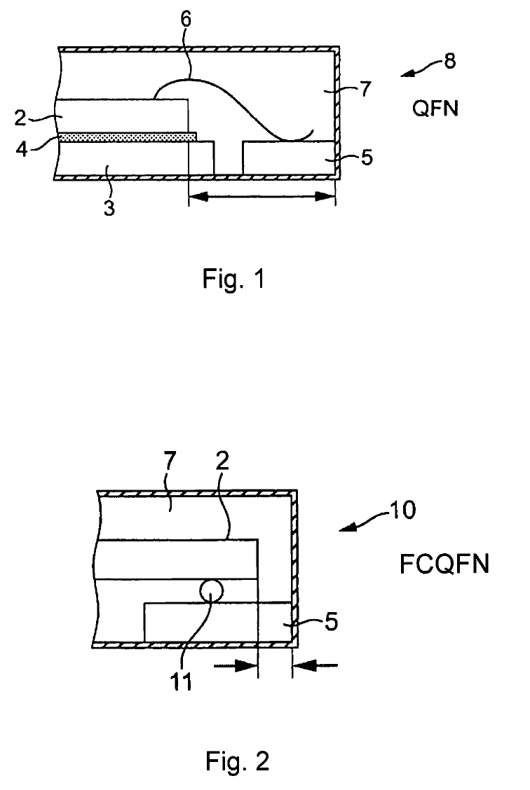

Common reference numerals are used throughout the figures to indicate similar features.

### DETAILED DESCRIPTION

Embodiments of the present invention are described below by way of example only. These examples represent the best ways of putting the invention into practice that are currently known to the Applicant although they are not the only ways in which this could be achieved. The description sets forth the functions of the example and the sequence of steps for constructing and operating the example. However, the same or equivalent functions and sequences may be accomplished by different examples.

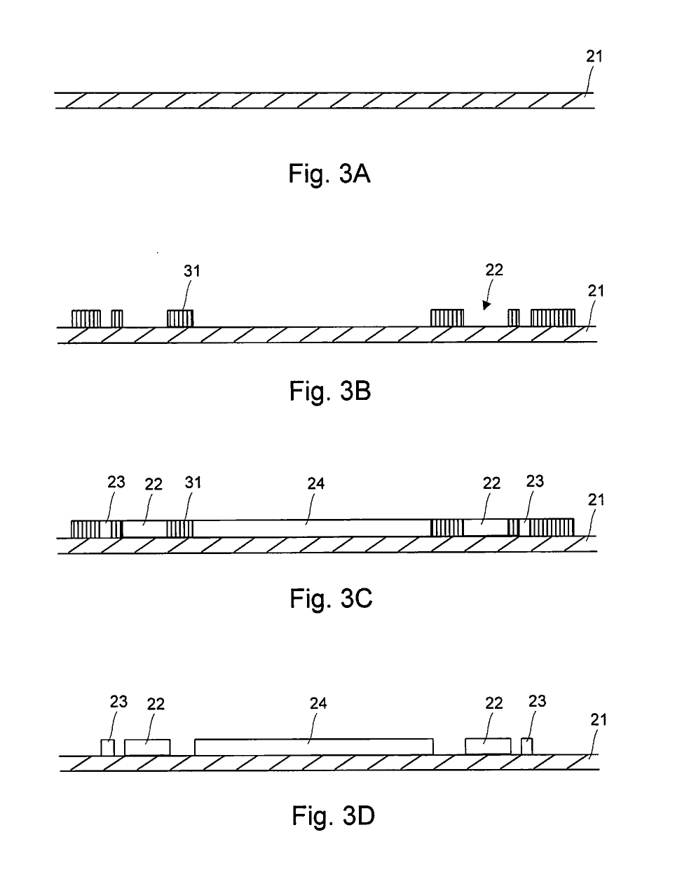

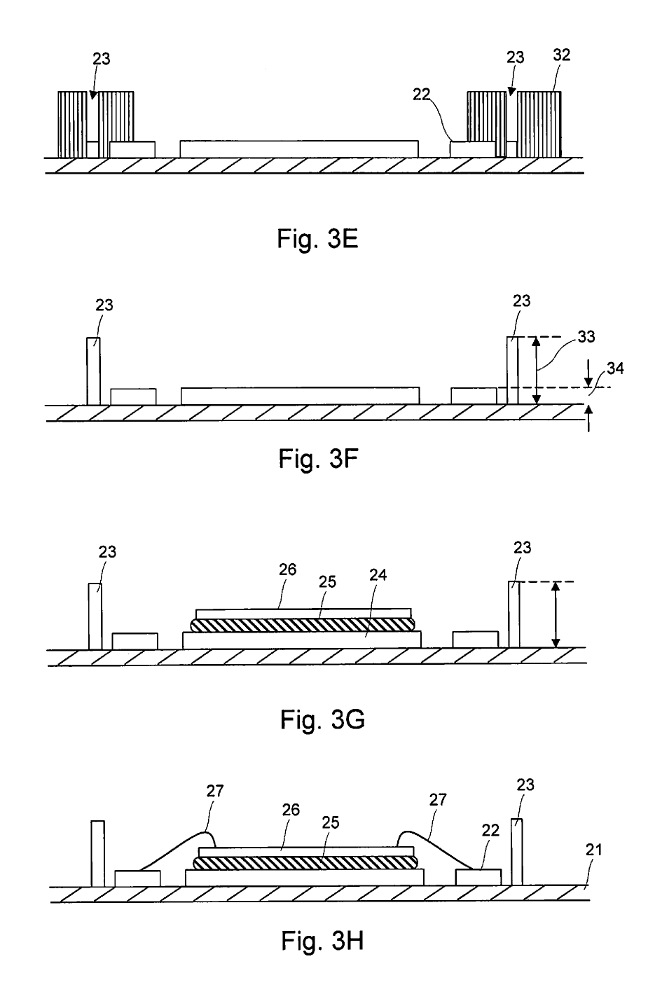

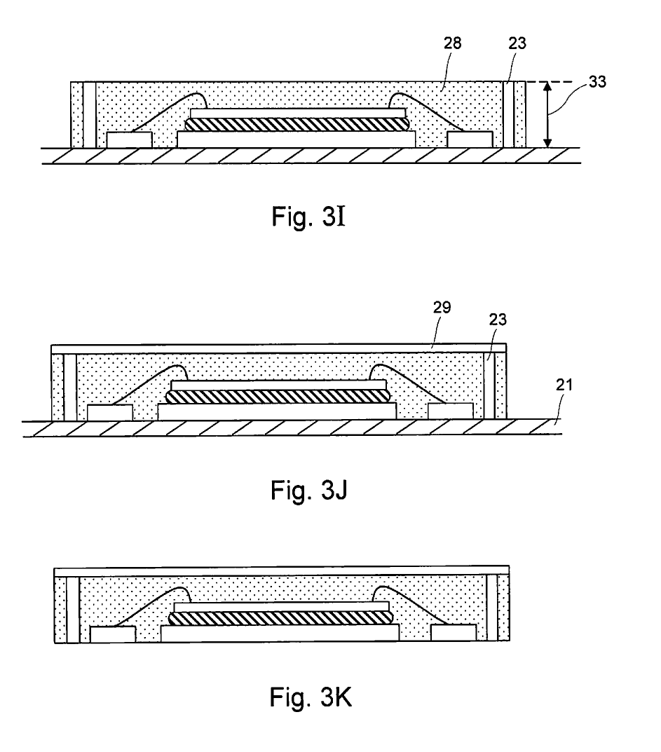

FIGS. 3A-3J show a sequence of stages of forming an example package. The example package shown in these Figures is a quad flat no-leads (QFN) package, although the technique can be applied to other types of package, such as a flip-chip on lead (FCQFN) package.

At FIG. 3A, a carrier 21 is provided. The carrier 21 provides support during the subsequent stages of the manufacturing process. The carrier 21 is a planar sheet that can be manufactured from any suitable material capable of withstanding the maximum excursion temperatures of the packaging process. Typical material examples include stainless steel or glass.

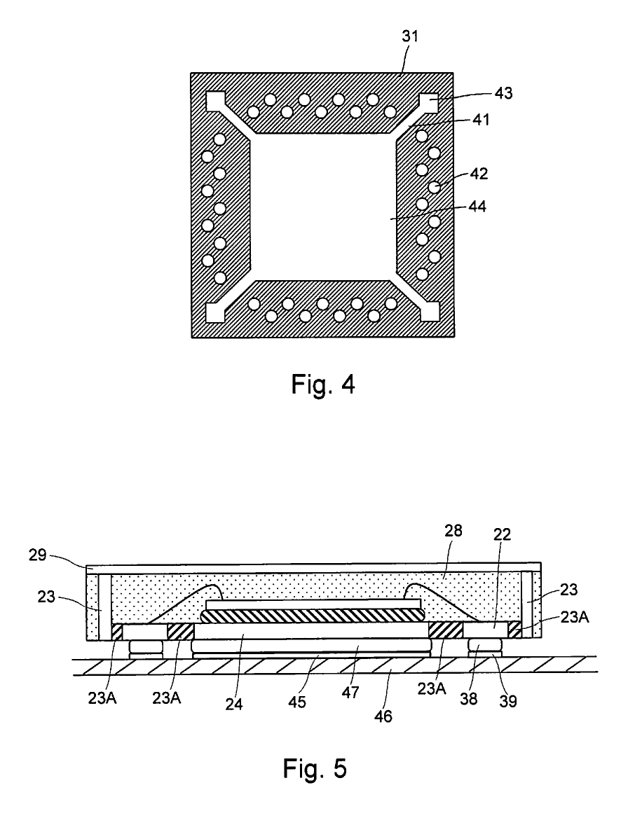

At FIG. 3B, a stencil 31 is applied to the surface of the carrier 21. The stencil 31 serves as mask or template, and defines regions 22 where elements of a lead frame will be formed. FIG. 4 shows a stencil 31 in plan view with open aperture regions 42 to define the areas 42 where elements of the lead frame will be formed. The stencil 31 also comprises: open regions 43 where pillars 23 will be formed; an open region 44 where a thermal pad 24 will be formed; and open regions 41 where links 23A connecting the pillars 23 to the thermal pad 24 will be formed. The thermal pad is a region of thermally conductive material which, in the final package, lies underneath the semiconductor die and conducts heat away from the die. The stencil 31 can be a material which is printed onto the surface of the carrier 21. The stencil 31 is a temporary layer and is subsequently removed. The stencil 31 can be removed after the stage shown in FIG. 3C, or can remain in place until a later stage, such as after FIG. 3E.

At FIG. 3C, a lead frame is formed on the carrier 21. Conductive material is deposited on the carrier 21 at locations where elements 22 of the lead frame are required. Elements 22 of the lead frame include contact pads of the package. Contact pads can also be called lands. In the final package, these provide electrical connection to/from a lower face of the package. Conductive material can be deposited in a central region of the package to serve as a thermal pad 24 for the die 26. The elements 22, 24 of the lead frame lie in a common plane, parallel to the plane of the carrier 21. The stencil 31 applied in FIG. 3B serves as a template for the conductive material deposited at FIG. 3C. The conductive material is a mixture of metal powder and a suspension component. The metal powder can be silver or copper. The conductive material can be applied by a screen printing process using the stencil 31 as a template to define open regions where elements of the lead frame will be formed. Alternatively, the conductive material can be applied by a 3D or inkjet printing process, where material is selectively deposited at precise locations on the carrier 21. If a 3D printing or ink jet printing technique is used to deposit the conductive material, then the stencil 31 shown in FIGS. 3B and 3C can be omitted and the conductive material can be deposited directly onto the carrier 21 at locations where it is required.

At FIG. 3C, conductive material is also deposited on the carrier 21 at one or more locations where at least one conductive pillar structure 23 is required. The pillar is formed of the same conductive material as the other elements of the lead frame. The stencil 31 applied at FIG. 3B also defines the regions where the at least one pillar is to be formed. The pillar structure(s) 23 and elements 22 of the lead frame are formed at the same time. Typically, the pillar is formed of the same material as the lead frame.

In a subsequent stage, not shown, the conductive material is subjected to a set of process conditions in which heat is applied for a defined period of time under a set of recommended environmental conditions which evaporates the suspension component of the paste to form a sintered solid at FIG. 3C. This stage may use only heat and time to form the sintered solid, or may use pressure, heat and time. A further alternative is that ultraviolet (UV) radiation can be used to sinter the particles of the conductive material if the particles are small enough and if exposure to the UV radiation generates enough energy in the particles. Once the sintering process is complete the stencil 31 can be removed. FIG. 3D shows the partly-manufactured package after the stencil 31 has been removed, leaving elements 22 of the lead frame and partially constructed pillars 23.

Conductive material is deposited in a plurality of stages to achieve a desired height of the at least one pillar 23. An example thickness of material deposited in a stage is 25 microns. The elements 22 of the lead frame may only require a single stage of deposition and sintering. The at least one pillar 23 may require multiple stages of material deposition. FIG. 3E shows a further stage of the manufacturing process, with a further stencil 32. Stencil 32 can be applied over other elements 22 of the lead frame, as shown in FIG. 3E. As before, the conductive material is subjected to the defined process conditions and the metal powder in the material applied at FIG. 3F is sintered. Once the process is complete the stencil 32 can be removed. Stencil 32 can be formed by laying down multiple layers of stencil material until a desired thickness is achieved. Alternatively, stencil 32 can be formed of the required final thickness in a single step.

FIG. 3F shows the partly-manufactured package after the stencil 32 has been removed. The conductive pillar structure 23 has a height 33 which is greater than a height 34 of the other elements of the lead frame. The required height 33 of the pillar will be determined by the sum of the parts including the die thickness 26, the die attach thickness 25, the wirebond height 27, the minimum acceptable distance between the loop height and the package surface and the thickness of the first sintered base layer of material 34. A semiconductor die has a typical thickness of 300 microns but can be considerably reduced by using conventional wafer lapping processes, which will influence the design of the final height of the pillar 23. The height of the conductive pillar 23, compared to other elements of the package design, is to allow the pillar 23 to conductively connected to a shield layer on an upper face of the final package. In the illustrated example the conductive pillar extends perpendicularly to the plane of the lead frame. After each stage of material deposition, the deposited material is cured, by using the recommended process conditions. The conductive material is a sintered material, such as metal.

At FIG. 3G a semiconductor die 26 is attached. Adhesive 25 secures the die 26 to the thermal pad 24.

At FIG. 3H the die 26 is connected to the elements 22 of the lead frame. In the case of a QFN package, as shown, wire bonds 27 connect between the semiconductor die 26 and contact pads 22 of the lead frame. FIG. 3A shows the package after the wire bonds 27 have been fitted.

The package shown in FIG. 3H is then encapsulated by an encapsulation material 28, such as a moulding compound. The encapsulation material 28 has electrically insulating properties. The encapsulation material 28 encapsulates the semiconductor die 26, the lead frame 22 and the at least one conductive pillar structure 23. In the example shown in FIG. 3I the encapsulation material 28 encapsulates the at least one conductive pillar structure 23 on all vertically extending sides. In another example (not shown) in which the at least one conductive pillar structure 23 is located on a perimeter of the package, the encapsulation material 28 may only encapsulate the at least one conductive pillar structure 23 on the inwardly-facing sides of the pillar structure 23. Outwardly-facing sides of the at least one conductive pillar structure 23 can remain exposed. In the finished package, the height of the moulding compound is no greater than the height of the pillars 23. The encapsulated package may require finishing (such as grinding or some other process) to provide a level upper surface of the moulding compound and to ensure the tops of the pillars are fully exposed. The upper surface of the pillars 23 require a good, clean conductive surface to provide a reliable contact for a shield. FIG. 3I shows the partly-manufactured package after the moulding compound has been applied and levelled.

At FIG. 3J a conductive layer 29 is added to the upper face of the encapsulated package. The conductive layer 29 conductively connects to the conductive pillars 23. The conductive layer 29 can be a pre-formed sheet of conductive material which is attached to the upper face of the package, such as by adhesive or welding to the pillars 23. Alternatively, the conductive layer 29 can be formed by depositing a conductive material on the upper surface in a similar manner as previously described for the lead frame and pillars 23. Finally, at FIG. 3K, the carrier 21 is removed from the underside of the package. The carrier 21 can be re-used.

FIG. 5 shows a package mounted to a printed circuit board. A contact pad 22 of the lead frame of the package connects, via a solder ball 38, to a pad 39 on the circuit board. A conductive pillar 23 of the package connects, via a solder ball 36, to a pad 37 on the circuit board. The conductive pillar 23 provides a via through the moulding compound 28. If the conductive material used to form the lead frame 22 is silver, then it is possible to solder directly to the lead frame. This reduces a stage compared to conventional etched copper lead frames, which require plating before they can be soldered. The thermal pad 24 connects to a ground plane region 45 on the PCB beneath the thermal pad 24. The cross-section also shows a link 23A connecting the pillar 23 to the thermal pad 24. Link 23A provides a thermally and/or electrically conductive path between the pillar 23 and the thermal pad 24.

The conductive layer 29 provides EMI shielding to the semiconductor die 26. The EMI shielding can shield the die from sources of EMI which are external to the package. Additionally, or alternatively, the EMI shielding can shield any device external to the package from EMI arising from the die 26. Additionally, or alternatively, the conductive layer 29 can conduct heat, and can help to spread/dissipate heat generated by the die 26. Links 23A connect pillars 23 to the thermal pad 24. The thermal pad 24 is typically connected to the PCB 45, 46 by solder 47. The PCB 46 may include thermal vias to dissipate the heat.

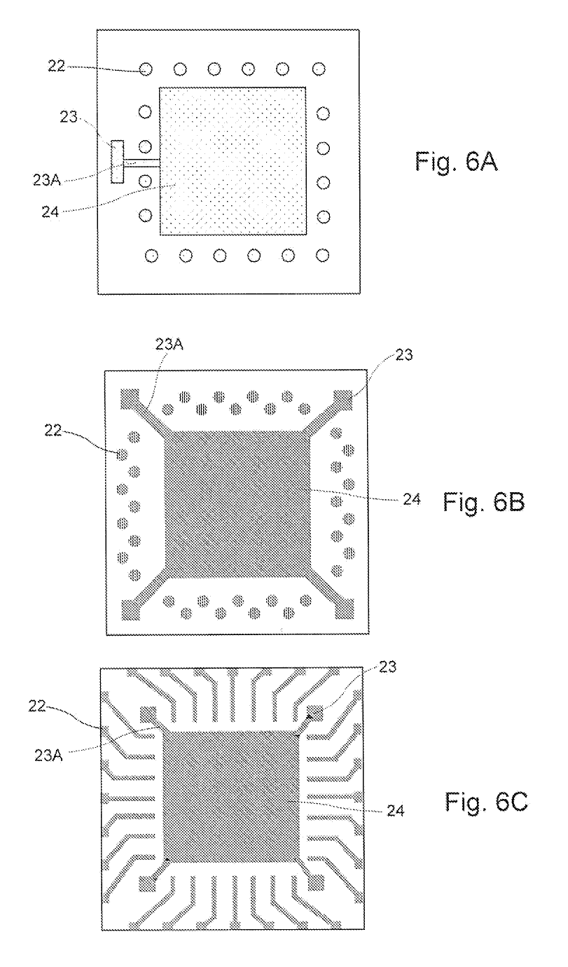

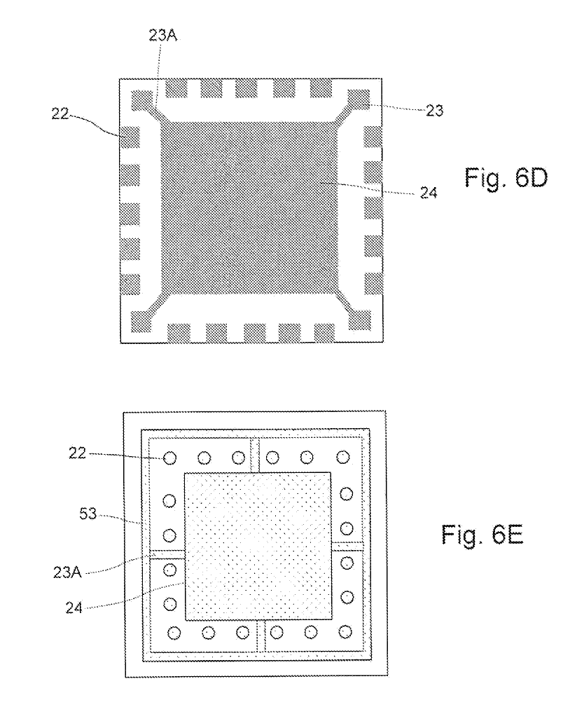

FIGS. 6A-6E show some examples of conductive structures which can be provided in a package as described above, to connect to the shield layer. Each of FIGS. 6A-6C show a package in plan view, with the shield layer removed. A set of contact pads 22 of the lead frame are shown. In FIG. 6A a single conductive pillar 23 is provided. The pillar 23 can be of the type previously shown in FIGS. 3C-3K. The pillar 23 can be provided at any location within the extent of the package, such as a corner or along a side. Although the pillar shown in FIG. 6A is offset inwardly from the perimeter of the package, the pillar can be provided on the perimeter of the package. A link 23A connects the pillar 23 to the thermal pad 24. In FIGS. 6B, 6C and 6D a plurality of pillars 23 of the type shown in FIG. 6A and FIGS. 3C-3K are provided around the package. In FIG. 6B the pillars 23 are located outside the set of contact pads 22 of the lead frame. FIG. 6B shows a set of four pillars 23 near corners of the package and links 23A connecting the pillars 23 to the thermal pad 24. FIG. 6C shows another example with a set of four pillars 23 in a different location to FIG. 6B. Tracks of the lead frame are also shown. The tracks connect pads 22 to a location inwardly of the pad, nearer to the thermal pad 24 and die 26. FIG. 6D shows another example with pillars 23 mounted near corners. A total cage is ideal but typically a total cage is not practical as inputs and outputs need to pass to/from the package. The spacing of the pillars will be limited by the chip design. In FIG. 6E a continuous wall 53 is provided around the package. The wall 53 is formed in the same manner as shown in FIGS. 3C-3K. The wall can be considered as a plurality of pillars which adjoin one another, or a pair of pillars with an additional structure connected between them. The wall 43 is located outside the set of contact pads 22 of the lead frame. Multiple links 23A connect the wall 53 to the thermal pad 24. A further alternative, not shown, is to provide a discontinuous wall formed of two or more wall sections. Although the wall 53 shown in FIG. 6E is offset inwardly from the perimeter of the package, the wall 53 can be provided on the perimeter of the package. Offsetting the pillars 23 and/or wall 53 inwardly from the perimeter of the package can ease dicing of individual packages from a sheet of packages. Although the examples of FIGS. 6A-6E show pillars having a circle or square cross-section, the pillars can have other shapes. For example, the pillars can have a rectangular cross-section.

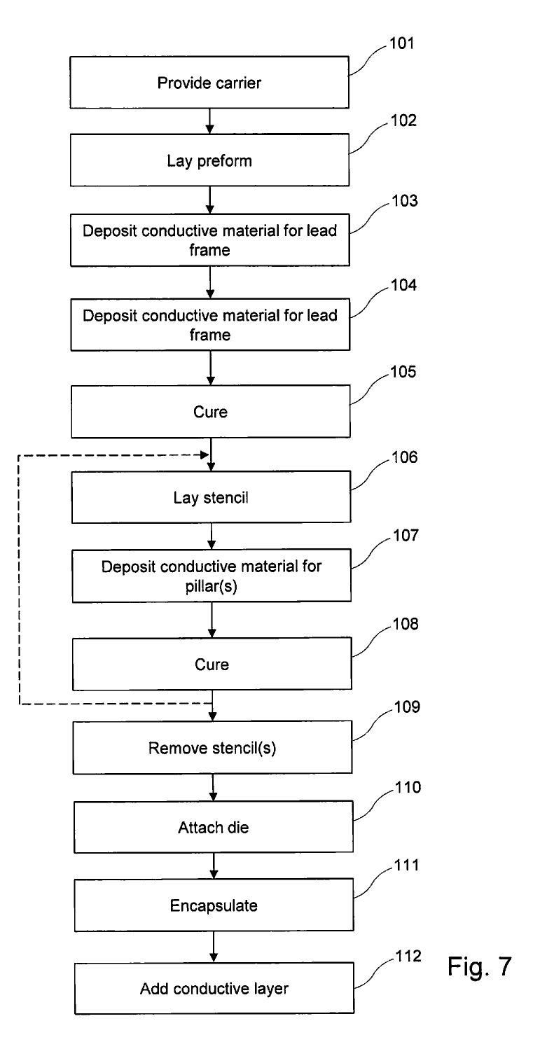

FIG. 7 shows an example method of packaging a semiconductor die. At block 101 a carrier is provided. If a screen printing process is used to apply the conductive material, then a stencil is laid on the carrier at block 102. At block 103 a lead frame is formed by depositing conductive material onto a surface of the carrier at locations where elements of the lead frame are required. At block 104 at least one conductive pillar structure is formed by depositing conductive material onto the surface of the carrier. Blocks 103 and 104 can be performed at the same time. The material deposited at blocks 103 and 104 can be cured at block 105. If required, at least one further iteration can be performed of blocks 106-108. At block 109 any stencil(s) are removed. At block 110 a semiconductor die is attached. At block 111 the semiconductor die, the lead frame and the at least one conductive pillar structure is encapsulated by applying encapsulating material (e.g. moulding compound) to form an encapsulated package. At block 111 a conductive layer is added to an upper face of the encapsulated package. As described above, some finishing of the encapsulating material and/or at least one pillar structure may be required before adding the conductive layer. The conductive layer conductively connects to the at least one conductive pillar. The carrier is removed in a final block (not shown).

The further iteration, or iterations, of blocks 106-108 provides the at least one conductive pillar structure with a height which is greater than a combined height of the semiconductor die, wire loop height, die attach, minimum separation between wire loop height and package top surface and the lead frame.

As the pillar structure(s) 23 and elements 22 of the lead frame are formed at the same time, this reduces the number of manufacturing process stage needed to provide a connection between a conductive shield layer. For example, the method described above does not require any further stages after the conductive shield layer has been fitted to the package.

Any range or device value given herein may be extended or altered without losing the effect sought, as will be apparent to the skilled person.

It will be understood that the benefits and advantages described above may relate to one embodiment or may relate to several embodiments. The embodiments are not limited to those that solve any or all of the stated problems or those that have any or all of the stated benefits and advantages.

Any reference to ‘an’ item refers to one or more of those items. The term ‘comprising’ is used herein to mean including the method blocks or elements identified, but that such blocks or elements do not comprise an exclusive list and a method or apparatus may contain additional blocks or elements.

The steps of the methods described herein may be carried out in any suitable order, or simultaneously where appropriate. Additionally, individual blocks may be deleted from any of the methods without departing from the spirit and scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. Although various embodiments have been described above with a certain degree of particularity, or with reference to one or more individual embodiments, those skilled in the art could make numerous alterations to the disclosed embodiments without departing from the spirit or scope of this invention.

1. An integrated circuit package comprising:
a semiconductor die;
a lead frame lying in a first plane;
at least one conductive pillar structure extending outwardly from the first plane, wherein the lead frame and the at least one conductive pillar structure are formed of sintered conductive material;
encapsulation material which encapsulates the semiconductor die, the lead frame and the at least one conductive pillar structure;
a conductive layer on an upper face of the package, the conductive layer conductively connecting to the at least one conductive pillar.

2. The package of claim 1 wherein the at least one conductive pillar structure has a height which is greater than a height of the lead frame.

3. The package of claim 1 wherein the at least one conductive pillar structure extends perpendicularly to the first plane.

4. The package of claim 1 comprising a plurality of the conductive pillars.

5. The package of claim 4 wherein the plurality of the conductive pillars are spaced around a perimeter of the lead frame.

6. The package of claim 1 wherein the at least one conductive pillar is located on a perimeter of the package.

7. The package of claim 1 wherein the at least one conductive pillar comprises a continuous wall of conductive material located around a perimeter of the lead frame.

8. The package of claim 7 wherein the wall is located on a perimeter of the package.

9. The package of claim 1 wherein the conductive layer forms at least one of: an EMI shield for the package and a thermal shield for the package.

10. The package of claim 1 wherein the conductive layer is a conductive sheet material.

11. The package of claim 1 wherein the conductive layer is sintered conductive material.

12. The package of claim 1 wherein the sintered conductive material is sintered metal.

13. The package of claim 1 wherein the sintered conductive material is sintered silver.

14. The package of claim 1 further comprising a thermal pad beneath the semiconductor die, and wherein a conductive path connects the at least one conductive pillar structure to the thermal pad.

15. A method of packaging a semiconductor die comprising:
forming a lead frame by depositing conductive material onto a surface of a carrier at locations where elements of the lead frame are required;
forming at least one conductive pillar structure by depositing the conductive material onto the surface of the carrier at a locations where the at least one conductive pillar structure is required, wherein the conductive material is sintered conductive material;
attaching a semiconductor die;
connecting the semiconductor die to the lead frame;
encapsulating the semiconductor die, the lead frame and the at least one conductive pillar structure to form an encapsulated package;
adding a conductive layer to an upper face of the encapsulated package, the conductive layer conductively connecting to the at least one conductive pillar; and
removing the carrier.

16. The method of claim 15 wherein the at least one conductive pillar structure has a height which is greater than a height of the lead frame.

17. The method of claim 15 wherein the forming at least one conductive pillar structure comprises a plurality of stages of depositing the conductive material with curing between the stages.

18. The method of claim 15 wherein adding a conductive layer comprises depositing a layer of the conductive material on the upper face of the encapsulated package.

19. The method of claim 15 wherein adding a conductive layer comprises attaching a conductive sheet to the upper face of the encapsulated package.

20. The method of claim 15 wherein forming the at least one conductive pillar structure by depositing the conductive material comprises one of:
screen printing the conductive material;
printing the conductive material.
